(19) United States
(12) Patent Application Publication
(10) Pub. No.: US 2026/0344516 A1
(43) Pub. Date: Oct. 29, 2026

(54) SEMICONDUCTOR DEVICES, CHIP PACKAGES AND MANUFACTURING METHODS THEREOF

(71) Applicant: Yangtze Memory Technologies Holding Co., Ltd., Wuhan (CN)

(72) Inventors: Min WEN, Wuhan (CN); Zhen PAN, Wuhan (CN); Xuan ZHENG, Wuhan (CN); Xiaoxin LIU, Wuhan (CN)

(21) Appl. No.: 19/272,462

(22) Filed: Jul. 17, 2025

(30) Foreign Application Priority Data
Apr. 27, 2025 (CN) 202510536967.X

(51) Int. Cl. H10W 90/00; H10B 80/00; H10D 80/30; H10P 52/00; H10W 20/20; H10W 20/43; H10W 20/48; H10W 70/05; H10W 80/00

(52) U.S. Cl. CPC H10W 90/00; H10B 80/00; H10D 80/30; H10P 52/00; H10W 20/20; H10W 20/43; H10W 20/48; H10W 70/095; H10W 80/312; H10W 80/327; H10W 90/792

(57) ABSTRACT

Systems, devices, and methods for managing a semiconductor device are provided. In one aspect, a semiconductor device includes a first semiconductor structure having a first substrate and a first contact structure; and a second semiconductor structure stacked over the first semiconductor structure along a first direction and having a second substrate and a second contact structure. The second semiconductor structure is coupled to the first semiconductor structure with the first contact structure being in contact with the second contact structure. The second substrate has a perimeter portion and a center portion along a second direction different from the first direction. Along the first direction, a thickness of the perimeter portion of the second substrate is smaller than a thickness of the center portion of the second substrate. Along the second direction, a size of the first substrate is greater than a size of the second substrate.

### CROSS-REFERENCE TO RELATED APPLICATIONS

This application claims priority to Chinese Patent Application No. 202510536967.X, filed on Apr. 27, 2025, which is hereby incorporated by reference in its entirety.

### TECHNICAL FIELD

The present disclosure relates to chip packages and fabrication processes for chip packages.

### BACKGROUND

Semiconductor devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

A chip package may be used to integrate one or more memory dies with other dies (e.g., a processor). In a chip package, different dies can be stacked vertically and coupled to one another through vias and contacts.

### SUMMARY

The present disclosure describes methods, devices, systems and techniques for chip packages with through-silicon-vias (TSVs) extending through thinned substrates.

One aspect of the present disclosure features a semiconductor device, including a first semiconductor structure having a first substrate and a first contact structure; and a second semiconductor structure stacked over the first semiconductor structure along a first direction and having a second substrate and a second contact structure, the second semiconductor structure being coupled to the first semiconductor structure with the first contact structure being in contact with the second contact structure along the first direction, where the second substrate has a perimeter portion and a center portion along a second direction different from the first direction, where, along the first direction, a thickness of the perimeter portion of the second substrate is smaller than a thickness of the center portion of the second substrate, and where, along the second direction, a size of the first substrate is greater than a size of the second substrate.

In some implementations, the semiconductor device includes a dielectric structure including a dielectric material between the first semiconductor structure and the second semiconductor structure, the dielectric structure including an air gap, and the air gap is closer to the perimeter portion of the second substrate of the second semiconductor structure than to the first semiconductor structure.

In some implementations, the thickness of the perimeter portion of the second substrate gradually decreases from a first side of the perimeter portion of the second substrate to a second side of the perimeter portion of the second substrate, the first side of the perimeter portion of the second substate being between the center portion of the second substrate and the second side of the perimeter portion of the second substrate.

In some implementations, the size of the first substrate is greater than the size of the second substrate by 10 μm to 100 μm.

In some implementations, the thickness of the center portion of the second substrate is in a range from about 3 μm to about 20 μm.

In some implementations, the thickness of the perimeter portion of the second substrate decreases by a value over a distance along the second direction, the value being between 50 nm and 1000 nm, the distance being smaller than 1000 um.

In some implementations, the second semiconductor structure includes a memory array having a plurality of memory cells, and the first semiconductor structure includes a circuitry configured to be coupled to the memory array through at least the first contact structure and the second contact structure.

In some implementations, the first contact structure and the second contact structure include at least one of micro-bumps, solder balls, or bonding pads.

In some implementations, the semiconductor device includes a through-silicon-via (TSV) extending through the second substrate of the second semiconductor structure along the first direction onto a corresponding second contact structure of the second semiconductor structure that is in contact with a corresponding first contact structure of the first semiconductor structure.

In some implementations, the semiconductor device includes a plurality of second semiconductor structures sequentially stacked over the first semiconductor structure along the first direction, the plurality of second semiconductor structures including the second semiconductor structure, the plurality of second semiconductor structures being coupled to one another through hybrid bonding.

In some implementations, the semiconductor device includes a plurality of through-silicon-vias (TSVs) extending through the plurality of second semiconductor structures along the first direction and coupling the plurality of second semiconductor structures to the first semiconductor structure, where the plurality of TSVs are stacked along the first direction and coupled to one another, and at least one TSV of the plurality of TSVs extends through a second substrate of a corresponding second semiconductor structure of the plurality of second semiconductor structures.

Another aspect of the present disclosure features a semiconductor device including: a first semiconductor structure including a first substrate and a first contact structure; a second semiconductor structure including a second substrate and a second contact structure, where the second semiconductor structure is stacked over the first semiconductor structure along a first direction, the second semiconductor structure is coupled to the first semiconductor structure with the first contact structure being in contact with the second contact structure along the first direction, the second substrate has an end portion and a center portion along a second direction different from the first direction, and, along the second direction, a size of the first substrate is greater than a size of the second substrate; and a filling layer at least partially surrounding the end portion of the second substrate, where the filling layer fills an undercut region that is under the end portion of the first substrate, and the undercut region is between the end portion of the second substrate and the first substrate.

In some implementations, the filling layer includes a first portion in contact with the end portion of the second substrate along the second direction, a second portion in the undercut region, and a third portion extending from the second portion along the second direction, and where the first portion has a first side in contact with the end portion of the second substrate and a second side opposite to the first side along the second direction, and a thickness of the first portion along the first direction decreases from the first side of the first portion to the second side of the first portion.

In some implementations, for the filling layer, the first portion is above the second portion and the third portion along the first direction.

In some implementations, the second semiconductor structure includes a memory array having a plurality of memory cells, and the first semiconductor structure includes a circuitry configured to be coupled to the memory array through at least the first contact structure and the second contact structure.

In some implementations, the semiconductor device includes: a through-silicon-via (TSV) extending through the second substrate of the second semiconductor structure along the first direction onto a corresponding second contact structure of the second semiconductor structure that is in contact with a corresponding first contact structure of the first semiconductor structure.

Another aspect of the present disclosure features a method including: providing a package including a base semiconductor structure and a second semiconductor structure that are stacked along a first direction, the base semiconductor structure including a base substrate, a circuitry and a first contact structure, the second semiconductor structure including a second substrate, a memory array and a second contact structure, the circuitry being coupled to the memory array by the first contact structure being in contact with the second contact structure, where, along a second direction different from the first direction, a size of the base substrate is greater than a size of the second substrate; polishing the second substrate of the second semiconductor structure to reduce a thickness of the second substrate along the first direction; and forming a first through-silicon-via (TSV) extending through the polished second substrate of the second semiconductor structure, the first TSV being coupled to the base semiconductor structure.

In some implementations, providing the package includes: providing the package including the base semiconductor structure and a plurality of second semiconductor structures including the second semiconductor structure, where there is an undercut region under the second substrate and between the second substrate and the base substrate, where the plurality of second semiconductor structures are stacked over the base semiconductor structure along the first direction, and the plurality of second semiconductor structures are spaced part from one another along the second direction.

In some implementations, the second substrate includes an end portion and a center portion along the second direction, and the undercut region is under the end portion, and, where, after polishing the second substrate, the end portion includes a perimeter portion having a thickness smaller than a thickness of the center portion.

In some implementations, the method includes depositing a filling material to form a filling layer between adjacent second semiconductor structures of the plurality of second semiconductor structures, where the filling material fills the undercut region; and polishing corresponding second substrates of the plurality of second semiconductor structures to reduce thicknesses of the corresponding second substrates along the first direction.

In some implementations, the method includes polishing second substrates of the plurality of second semiconductor structures to reduce thicknesses of the second substrates along the first direction; forming TSVs through corresponding polished second substrates of the plurality of second semiconductor structures, the TSVs including the first TSV; and after forming the TSVs through the corresponding polished second substrates, cutting the package into a plurality of chip packages, a chip package of the plurality of chip packages including a portion of the base semiconductor structure and a corresponding second semiconductor structure of the plurality of second semiconductor structures that is stacked over the portion of the base semiconductor structure.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a cross-sectional view of an example of a semiconductor device.

FIGS. 1B and 1C illustrate enlarged views of edge portions of the semiconductor device of FIG. 1A.

FIG. 1D illustrates an enlarged view of a center portion of the semiconductor device of FIG. 1A.

FIG. 2A illustrates a cross-sectional view of another example of a semiconductor device.

FIG. 2B is an enlarged view of an edge portion of the semiconductor device of FIG. 2A.

FIG. 2C illustrates a plan view of the semiconductor device of FIG. 2A.

FIGS. 3A-3G illustrate cross-sectional views of a semiconductor device at various stages of a manufacturing process.

FIGS. 4A-4H illustrate cross-sectional views of a semiconductor device at various stages of a manufacturing process.

FIG. 5 is a flowchart of a process of an example method of forming a semiconductor device.

FIG. 6 illustrates a block diagram of a system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

In a chip package, memory devices can be stacked vertically on a base structure (e.g., a base die). The stacked memory devices can share a common interface (e.g., an interposer) for communication with a processor. Through-silicon-vias (TSVs) can be formed extending vertically through corresponding memory devices to establish communications between the memory devices and the base structure. TSVs can be vertical holes that extend through the memory devices and are filled with a conductive material. In some examples, a thickness of the semiconductor device (e.g., a die) can be around 30 μm to 200 μm. A thick substrate in the semiconductor device may lead to an increase in the critical dimension (CD) and depth of TSVs during the formation of the chip package, because the aspect ratio of the TSVs need be below some levels for ease of manufacturing. Additionally, thick substrate may also limit a reduction of pitch of the TSVs. As the TSVs can be used as input/output (I/O) channels, the pitch of the TSVs can be related to the input/output (I/O) density. Therefore, increasing I/O density in the chip package can be challenging.

Implementations of the present disclosure provide semiconductor devices and methods to form such semiconductor devices. In some implementations, a semiconductor device includes a first semiconductor structure having a first substrate and a first contact structure; and a second semiconductor structure stacked over the first semiconductor structure along a first direction and having a second substrate and a second contact structure. The second semiconductor structure is coupled to the first semiconductor structure with the first contact structure being in contact with the second contact structure. The second substrate has a perimeter portion and a center portion along a second direction different from the first direction. Along the first direction, a thickness of the perimeter portion of the second substrate is smaller than a thickness of the center portion of the second substrate. Along the second direction, a size of the first substrate is greater than a size of the second substrate.

Implementations of the present disclosure can provide one or more of the following technical advantages, effect, and/or benefits. For example, the techniques disclosed in the present disclosure can provide a higher I/O density and a better signal quality in a high bandwidth memory (HBM) device. For example, the substrate thickness of a memory die of the HBM dice can be reduced by a polishing process. A thinner substrate can allow a shallower TSV to be formed that extends through the substrate. Shallower TSVs can improve signal quality with less signal loss. Additionally, shallower TSVs allow for a reduction of the size (e.g., CD) of the TSVs while maintaining its aspect ratio at a suitable range. Further, without being limited to any particular theory, a thinner substrate can reduce mechanical stress during the manufacturing process, thereby allowing TSVs to be placed closer together with reduced mechanical failures. Therefore, with a thinned substrate, TSVs can have a smaller lateral size (e.g., CD) and a smaller pitch, thereby increasing the I/O density of the semiconductor device. A thinner substrate can also allow for a more compact chip package.

In addition, the techniques disclosed in the present disclosure can reduce a risk of peeling of a memory die in the chip package. For example, in some implementations, before polishing the substrate of a memory die, a filling layer can be deposited. The filling layer can fill an undercut region that is under an edge region (or a perimeter region) of the substrate. The filling layer can be deposited by atomic layer deposition (ALD). ALD may offer better thickness control and uniformity. Therefore, the filling layer may reduce air gaps in the region near the substrate edge. Reducing air gaps can reduce the risk of peeling (e.g., peeling of the substrate). Without being limited to any particular theory, air gaps can create areas where the adhesion between layers are weak, and the air gaps may also create an area where mechanical stress can be concentrated. The weak adhesion and concentration of stress can cause the layer to lift or peel off more easily. With reduced air gaps or eliminated air gaps, the chip package can be more mechanically reliable.

Further, the techniques described in the present disclosure can improve yield by employing die-to-wafer bonding techniques. For example, know good memory dies (e.g., pretested, functional dies) can be used in forming a chip package by sequentially stacking them vertically on a base die. Attaching only good memory dies to a wafer during the bonding process can significantly improve yield of the chip package compared to wafer-to-wafer bonding, as wafers may include defective dies. Die-to-wafer bonding also allows heterogeneous integration where stacked dies can be different. For example, the stacked dies can include a memory die and a control die. In another example, the stacked dies can include a DRAM die and a NAND die.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

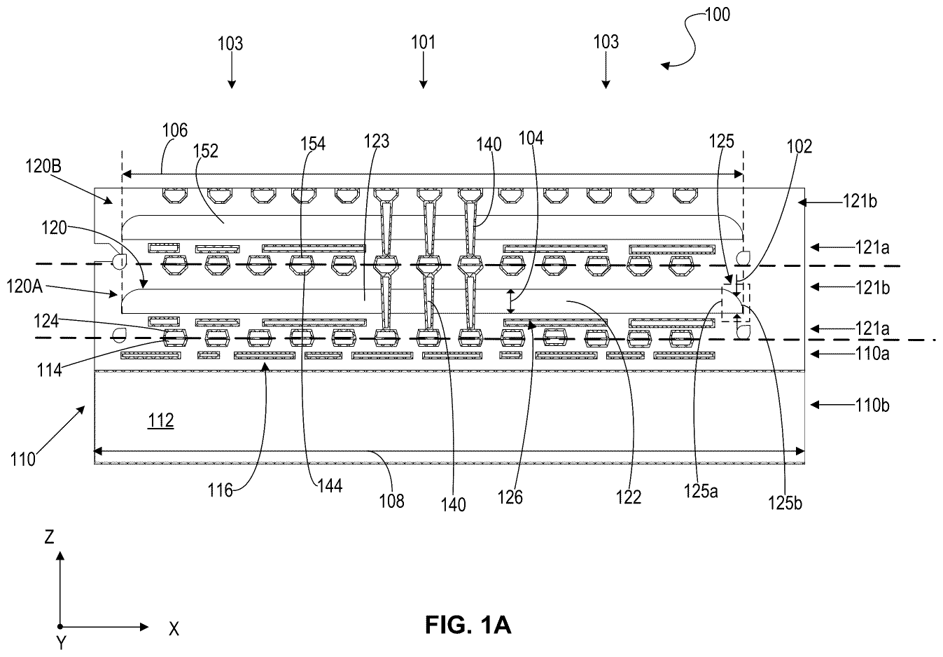

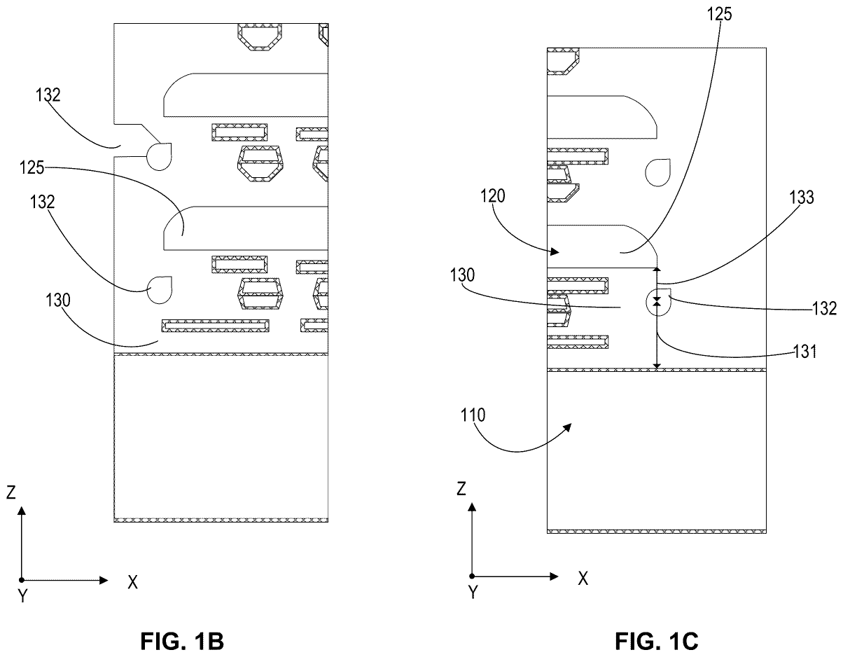

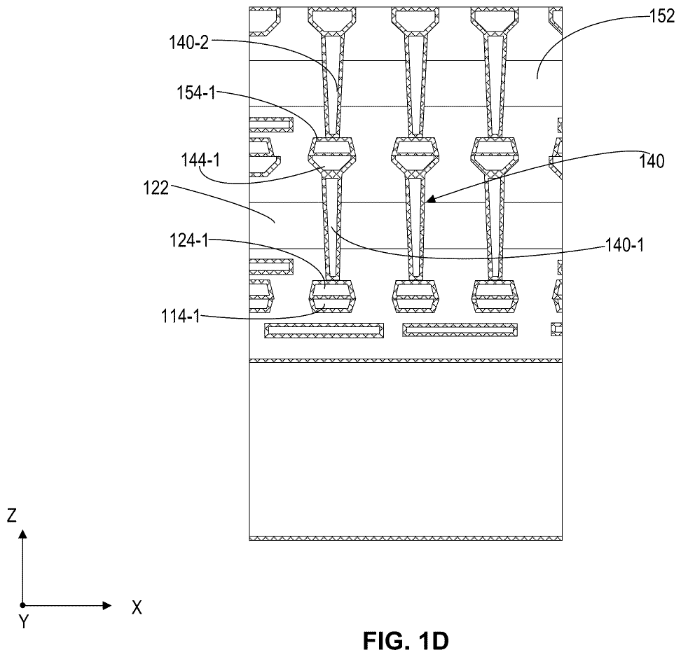

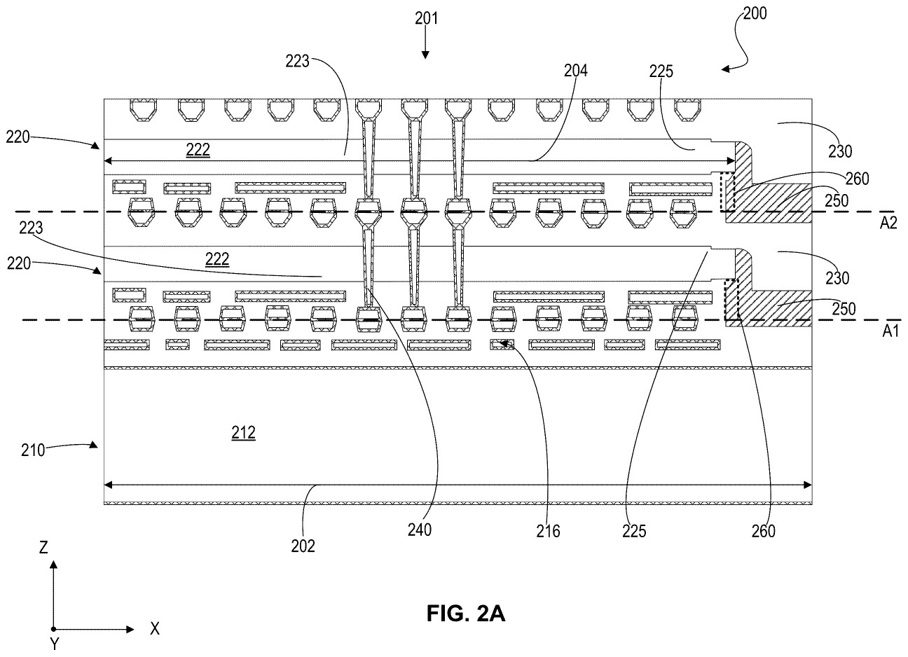

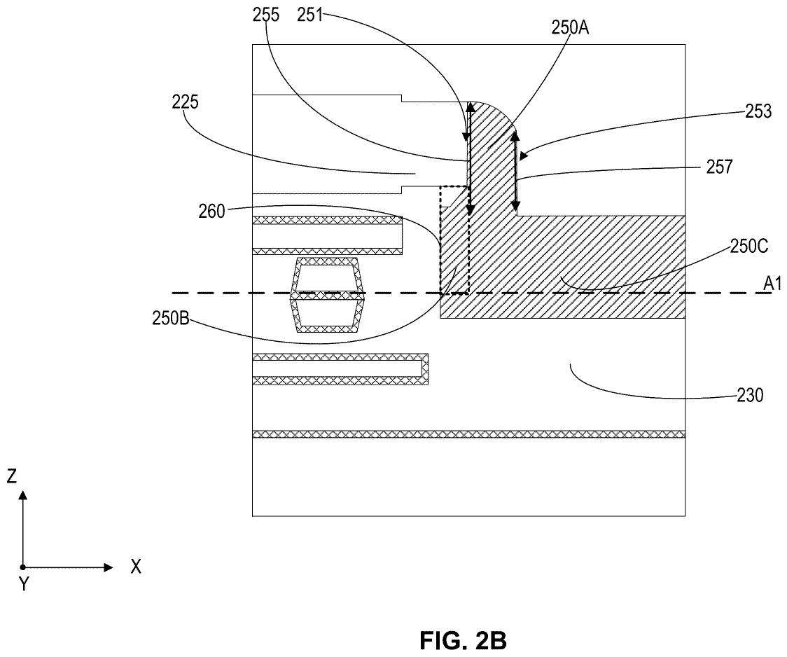

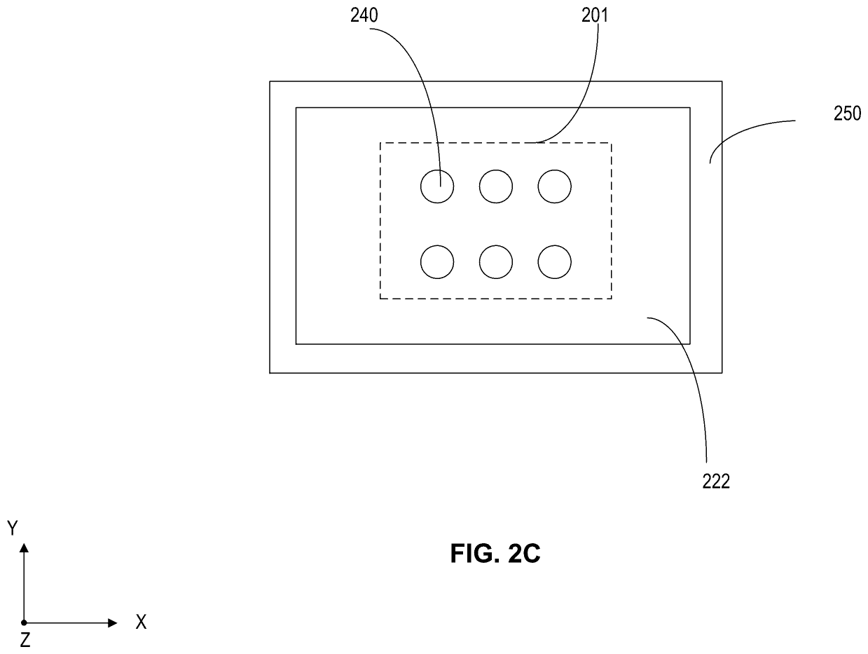

FIG. 1A illustrates a cross-sectional view of an example of a semiconductor device 100. FIGS. 1B and 1C illustrate enlarged views of edge portions of the semiconductor device 100 of FIG. 1A. FIG. 1D illustrates an enlarged view of a center portion of the semiconductor device 100 of FIG. 1A. The semiconductor device 100 can also be referred to as a chip package 100 in the present disclosure. It is noted that X, Y, and Z axes (also referred to as X, Y, and Z directions) are included in FIGS. 1A-1D (and also FIGS. 2A-4H) to further illustrate the spatial relationship of various components in a semiconductor device. A substrate of a semiconductor structure (e.g., a first semiconductor structure 110, or a second semiconductor structure 120) can include two lateral surfaces extending laterally in the X-Y plane: a top (or upper) surface and a bottom (or lower) surface opposite to the top surface of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the first semiconductor structure in the Z direction (the vertical direction perpendicular to the X-Y plane, e.g., the thickness direction of the substrate). The same notion for describing the spatial relationships is applied throughout the present disclosure.

In some implementations, the semiconductor device 100 is an HBM chip. The semiconductor device 100 includes a first semiconductor structure 110. The first semiconductor structure 110 includes a first substrate 112. The first substrate 112 can include silicon (e.g., single crystalline silicon, c-Si), SiGe, GaAs, Ge, silicon on insulator (SOI), or any other suitable materials. The first semiconductor structure 110 can include circuitry 116 on the first substrate 112. In some implementations, the first semiconductor structure 110 is a base die for the HBM chip, and the circuitry 116 includes at least one of direct access (DA) ports or PHY interface. The DA port can provide testing channels for the memory devices (e.g., the second semiconductor structures 120A, 120B) in the HBM chip, and the PHY interface can connect the memory devices to a processor or a controller. In some implementations, the circuitry 116 includes a plurality of transistors (e.g., planar transistors and/or 3D transistors). Trench isolations (e.g., shallow trench isolations (STIs)) and doped regions (e.g., wells, sources, and drains of transistors) can be formed on or in the first substrate 112 as well. In some examples, the circuitry 116 is formed using complementary metal-oxide-semiconductor (CMOS) technology.

The first semiconductor structure 110 can further include at least one first contact structure 114 at an upper surface of the first semiconductor structure. The first contact structure 114 can be disposed on the circuitry 116 along a vertical direction (e.g., Z direction). In some implementations, the first contact structure 114 includes at least one of micro-bumps, solder balls, pillars, or bonding pads. The first contact structure can include conductive materials, including without limitation to, W, Co, Cu, Al, TiN, TaN, polysilicon, silicide, or any combination thereof. The first contact structures 114 can be laterally spaced apart (e.g., along X direction) and isolated from each other by a dielectric material (e.g., silicon oxide). The first contact structures 114 can be coupled to the circuitry 116.

Although not shown, it is understood that, in some implementations, the first semiconductor structure 110 can have through-silicon-contact or TSVs that extend through the first substrate 112 and couple to an interposer that is disposed below the first semiconductor structure 110. The interposer can couple the first semiconductor structure 110 to another device (e.g., a processor, or a controller).

The semiconductor device 100 further includes a second semiconductor structure 120 stacked over the first semiconductor structure 110 along a vertical direction (e.g., Z direction). The second semiconductor structure 120 has a second substrate 122. The second substrate 122 can have the same or different material as the first substrate 112. In some implementations, the second substrate 122 includes silicon (e.g., single crystalline silicon, c-Si), SiGe, GaAs, Ge, SOI, or any other suitable materials. The second semiconductor structure 120 can be a memory device and include at least one memory array 126 on a first side of the second substrate 122. The first side of the second substrate 122 can refer to the side that faces the first semiconductor structure 110. Therefore, the second semiconductor structure 120 can be stacked over the first semiconductor structure 110 in a face-face manner. In other words, the memory arrays 126 of the second semiconductor structure 120 can face the circuitry 116 of the first semiconductor structure 110, and the first and second substrates 112, 122 can oppose to each other along Z direction. Each memory array 126 of the second semiconductor structure 120 can include a plurality of memory cells. The memory cells can be DRAM memory cells, NAND memory cells, ferroelectric memory cells, or any other suitable memory cells. In some implementations, the memory arrays 126 are DRAM memory arrays.

In some implementations, along a lateral direction (e.g., X direction), a size 108 of the first substrate 112 is greater than a size 106 of the second substrate 122. In some implementations, the size of the first substrate 112 is greater than the size of the second substrate 122 by 10 μm to 100 μm. As described with further details below, the greater size of the first substrate 112 can result from a die to wafer bonding process.

The second semiconductor structure 120 includes at least one second contact structure 124 at the lower surface of the second semiconductor structure 120. The lower surface of the second semiconductor structure 120 can be in contact with the upper surface of the first semiconductor structure 110. In some implementations, the second contact structure 124 includes at least one of micro-bumps, solder balls, pillars, or bonding pads. The second contact structures 124 can be the same as or different from the first contact structures 114. The second contact structures 124 can be laterally spaced apart (e.g., along X direction) and isolated from each other by a dielectric material (e.g., silicon oxide). The second contact structures 124 can be coupled to the memory arrays 126.

The first and second semiconductor structures 110, 120 can be coupled to each other with the first contact structure 114 being in contact with the second contact structure 124 along Z direction. In some examples, both the first and second contact structures 114, 124 can include bonding pads, and the first and second semiconductor structures 110, 120 can be bonded through hybrid bonding. A hybrid bonding can include a combination of metal-to-metal bonding (e.g., by bonding pads) and a direct oxide to oxide bonding (e.g., by dielectric layers that isolate adjacent bonding pads). In some other examples, the second contact structures 124 can include micro-bumps or solder balls, and the first contact structures 114 can include conductive pads or conductive structures that are coupled to the micro-bumps or solder balls. In additional examples, the first contact structures 114 can include micro-bumps or solder balls, and the second contact structures 124 can include conductive pads or conductive structures that are coupled to the micro-bumps or solder balls. In some implementations, the memory array 126 of the second semiconductor structure 120 is coupled to the circuitry 116 of the first semiconductor structure 110 through at least one of the first contact structures 114 and the second contact structures 124.

The second substrate 122 has a perimeter portion 125 and a center portion 123 arranged along a lateral direction (e.g., X direction). The perimeter portion 125 can laterally surround the center portion 123. As illustrated in FIG. 1A, in some implementations, the perimeter portion 125 of the second substrate 122 has an edge roll-off profile (e.g., due to a polishing process as described with further details below). The thickness of the perimeter portion 125 can gradually decrease from a first side 125a of the perimeter portion 125 to a second side 125b of the perimeter portion 125. The first side 125a of the perimeter portion 125 of the second substrate 122 is between the center portion 123 and the second side 125b of the perimeter portion 125. For example, the perimeter portion 125 can have a gradual slope, where it gradually decreases from the center uniform thickness (e.g., the thickness 104) to a thinner region near the edge. The gradual slope can have a curved profile, as shown in FIG. 1A. In some implementations, along Z direction, a thickness 102 of the perimeter portion 125 of the second substrate 122 is smaller than a thickness 104 of the center portion 123 of the second substrate 122. The thickness 102 of the perimeter portion 125 can refer to an average thickness of the perimeter portion 125. In some implementations, the thickness 104 of the center portion 123 of the second substrate 122 is in a range from about 3 μm to about 20 μm. In some implementations, the thickness 102 of the perimeter portion 125 of the second substrate 122 is smaller than the thickness 104 of the center portion 123 by 50 nm to 1000 nm. In some implementations, the thickness of the perimeter portion 125 of the second substrate 122 decreases by a value over a distance along X direction, where the value is between 50 nm and 1000 nm, and the distance is smaller than 1000 μm. In an example, the thickness of the perimeter portion 125 of the second substrate 122 can decrease 100 nm over a distance of 500 μm. In another example, the thickness of the perimeter portion 125 of the second substrate 122 can decrease 500 nm over a distance of 800 μm. In yet another example, the thickness of the perimeter portion 125 of the second substrate 122 can decrease 1000 nm over a distance of 300 μm.

Referring now to FIGS. 1B and 1C, in some implementations, the semiconductor device 100 includes a dielectric structure 130 between the first semiconductor structure 110 and the second semiconductor structure 120. The dielectric structure 130 includes at least one dielectric material, including, but not limited to, silicon oxide, silicon nitride, silicon oxynitride, or any combination thereof. The dielectric structure 130 can include at least one air gap 132. The air gap 132 can include air and/or other gas (e.g., gas generated during a deposition process) and have regular or irregular shape. The air gap 132 can be surrounded by the dielectric structure 130. The air gap 132 can be adjacent to the perimeter portion 125 of the second substrate 122. The air gap 132 can be closer to the perimeter portion 125 of the second substrate 122 of the second semiconductor structure 120 than to the first semiconductor structure 110. For example, as shown in FIG. 1C, a distance 133 between the air gap 132 and the perimeter portion 125 of the second substrate 122 is smaller than a distance between the air gap 132 and the first semiconductor structure 110. In some implementations, as shown in FIGS. 1B and 1C, the air gap 132 is at least partially overlapped with the first and second semiconductor structures 110, 120 along a vertical direction (e.g., Z direction).

Referring now to FIG. 1D, the semiconductor device 100 includes at least one TSV 140 extending through the second substrate 122 of the second semiconductor structure 120 along Z direction onto a corresponding second contact structure 124 of the second semiconductor structure 120 that is in contact with a corresponding first contact structure 114 of the first semiconductor structure 110. For example, as shown in FIG. 1D, a TSV 140-1 extends vertically through the second substrate 122 onto a second contact structure 124-1. The second contact structure 124-1 can be in contact with the first contact structure 114-1. Therefore, the TSV 140-1 can be coupled to the first semiconductor structure 110 through the second contact structure 124-1 and the first contact structure 114-1. As shown in FIG. 1D, a plurality of TSVs 140 can extend vertically through the second substrate 122 and couple to the first semiconductor structure 110. The TSVs 140 can be used to power the second semiconductor structure 120 and/or used as input/output (I/O) channels.

Returning to FIG. 1A, in some implementations, the semiconductor device 100 includes a plurality of second semiconductor structures 120 sequentially stacked over the first semiconductor structure 110 along the Z direction. The example implementation in FIG. 1A shows two second semiconductor structures (e.g., two memory devices). The two second semiconductor structures can be stacked together along Z direction. For ease of description, the lower second semiconductor structure 120 can be referred to as a first memory structure 120A, while the upper second semiconductor structure 120 can be referred to as a second memory structure 120B in the present disclosure. In some implementations, the plurality of second semiconductor structures 120 have same or substantially similar structures. For example, similar to the first memory structure 120A, the second memory structure 120B can also have an edge roll-off in the perimeter region, and the average thickness of the substrate of the second memory structure 120B can be equal to or substantially similar as that of the first memory structure 120A. Additionally, the dielectric structure 130 may have at least one air gap 132 between the first and second memory structures 120A, 120B, and the air gap 132 can be adjacent to the perimeter portion 125 of the substrate of the second memory structure 120B.

In some implementations, the plurality of second semiconductor structures 120 include a same type of memory arrays, e.g., DRAM. In some implementations, the plurality of second semiconductor structures 120 include different types of memory arrays. For example, the first memory structure 120A can include DRAM, while the second memory structure 120B can include NAND. In some implementations, the plurality of second semiconductor structures 120 include dies with different functions. For example, the lower second semiconductor structure 120A is a memory die, while the upper second semiconductor structure 120B is a control die.

In some implementations, the plurality of second semiconductor structures 120 are coupled to one another through hybrid bonding, micro-bumps (e.g., μbumps), pillars, or solder balls. For example, a second side 121b (e.g., the upper side) of the first memory structure 120A can have at least one third contact structures 144 that are laterally spaced apart and separated from each other by a dielectric material. The first side 121a (e.g., the lower side) of the second memory structure 120B can have at least one fourth contact structures 154 that are laterally spaced apart and separated from each other by a dielectric material. At least one third contact structure 144 can be in contact with a corresponding one of fourth contact structures 154. In an example, the contact structures 144, 154 can be bonding pads for hybrid bonding. In another example, the third contact structures 144 can be micro-bumps, pillars, or solder balls, and the corresponding fourth contact structures 154 can be a conductive pad or conductive structures that are coupled to the micro-bumps, pillars, or solder balls.

Referring to both FIGS. 1A and 1D, the semiconductor device 100 includes a plurality of stacked TSVs 140 extending through the plurality of second semiconductor structures 120 along the Z direction and coupling the plurality of second semiconductor structures 120 to the first semiconductor structure 110. The plurality of TSVs 140 can be stacked along the Z direction and coupled to one another through corresponding contact structures. For example, as illustrated in FIG. 1D, the upper TSV 140-2 can be stacked over the lower TSV 140-1 along the Z direction and coupled to each other through the third contact structure 144-1 and the corresponding fourth contact structure 154-1. As the lower TSV 140-1 is coupled to the first semiconductor structure 110, the upper TSV 140-2 can thereby be coupled to the first semiconductor structure 110 through the lower TSV 140-1.

With continued reference to FIGS. 1A and 1D, in some implementations, at least one TSV 140 extends through each second substrate 122. In other words, one or more TSVs 140 can be arranged laterally that extend through the same substrate. The example implementation in FIGS. 1A and 1D illustrates that three TSVs 140 can be arranged laterally along X direction, and they extend through the same substrate (e.g., the second substrate 122). Although not shown, the TSVs can also be arranged along a second lateral direction (e.g., as illustrated in FIG. 2C, where TSVs 240 can be arranged along both X and Y directions).

As illustrated in FIG. 1A, each of the second semiconductor structures 120 can have at least one TSV region 101 and at least one device region 103. The TSVs 140 can be disposed in the TSV region 101, while the memory arrays 126 can be disposed in the device region 103. In some implementations, the TSV region 101 is in the center of the corresponding second semiconductor structure 120 and surrounded by the device region 103, as shown in FIG. 1A. It is to be understood that the example arrangement in FIG. 1A is for illustration purpose and is not intended to be construed in a limiting sense. Other suitable arrangements of TSV and device regions 101, 103 can also be employed. For example, the TSV region 101 can be near the edge of the corresponding second semiconductor structure 120, while the device region 103 can be in the center and surrounded by the TSV region 101. In some implementations, the TSV regions 101 of different second semiconductor structures 120 can be stacked along the vertical direction (e.g., Z direction) such that the TSVs 140 inside the TSV regions 101 can be stacked vertically. For example, the TSV region 101 of the second memory structure 120B can be vertically stacked over the TSV region 101 of the first memory structure 120A along Z direction.

FIG. 2A illustrates a cross-sectional view of another example of a semiconductor device 200. FIG. 2B is an enlarged view of an edge portion of the semiconductor device 200 of FIG. 2A. FIG. 2C illustrates a plan view of the semiconductor device 200 of FIG. 2A. The semiconductor device 200 can also be referred to as a chip package 200 in the present disclosure. The semiconductor device 200 differs from the semiconductor device 100 primarily in a filling layer 250. Most of components included in the semiconductor device 200 described below and materials included in the components may substantially be the same as or similar to those of the semiconductor device 100 described above with reference to FIGS. 1A to 1D. Thus, for brevity, the following description will mainly focus on the differences between the semiconductor device 100 and the semiconductor device 200. For ease of description, reference will be made to FIGS. 2A-2C when describing the structure of the semiconductor device 200.

As illustrated in FIG. 2A, similar to the semiconductor device 100, the semiconductor device 200 includes a first semiconductor structure 210 (e.g., a base die) that includes a first substrate 212 and a first contact structure 214. The semiconductor device 200 also includes at least one second semiconductor structure 220 (e.g., at least one memory die). The at least one second semiconductor structure 220 can be coupled to the first semiconductor structure 210 through stacked TSVs. Each second semiconductor structure 220 includes a second substrate and a second contact structure. The second semiconductor structure 220 can be stacked over the first semiconductor structure 210 along a first direction (e.g., Z direction), and the second semiconductor structure 220 is coupled to the first semiconductor structure 210 with the first contact structure being in contact with the second contact structure along the first direction. Additionally, the second substrate can have an end portion 225 and a center portion 223 along a X direction. The size 202 of the first substrate 212 can be greater than a size 204 of the second substrate 222 along the X direction.

In some implementations, different from the semiconductor device 100, the semiconductor device 200 includes a filling layer 250 that is at least partially surrounding the end portion 225 of the second substrate 222. It is to be noted although the filling layer 250 depicted in FIG. 2A is located only near the right end portion 225 of the second substrate 222, the filing layer can also be present near the left end portion 225 of the second substrate 222. Tuning briefly to FIG. 2C, the filling layer 250 can be surrounding the second substrate 222 along its perimeter edge in both lateral directions (e.g., X and Y directions). It is further to be noted that although FIG. 2C illustrates the second substrate 222 has a rectangular shape, other shapes can also be possible. For example, the second substrate 222 can have a square shape, a circular shape, or an irregular shape.

Returning to FIG. 2A, the filling layer 250 can be below the dielectric structure 230. In some implementations, the filling layer 250 and/or the dielectric structure 230 includes dielectric materials including, but not limited to, silicon oxide, silicon nitride, silicon oxynitride, or any combination thereof. The filling layer 250 can have a different material compared to the dielectric structure 230. For example, the filling layer 250 can include silicon nitride, while the dielectric structure 230 can include silicon oxide. In some implementations, the filling layer 250 is deposited using ALD.

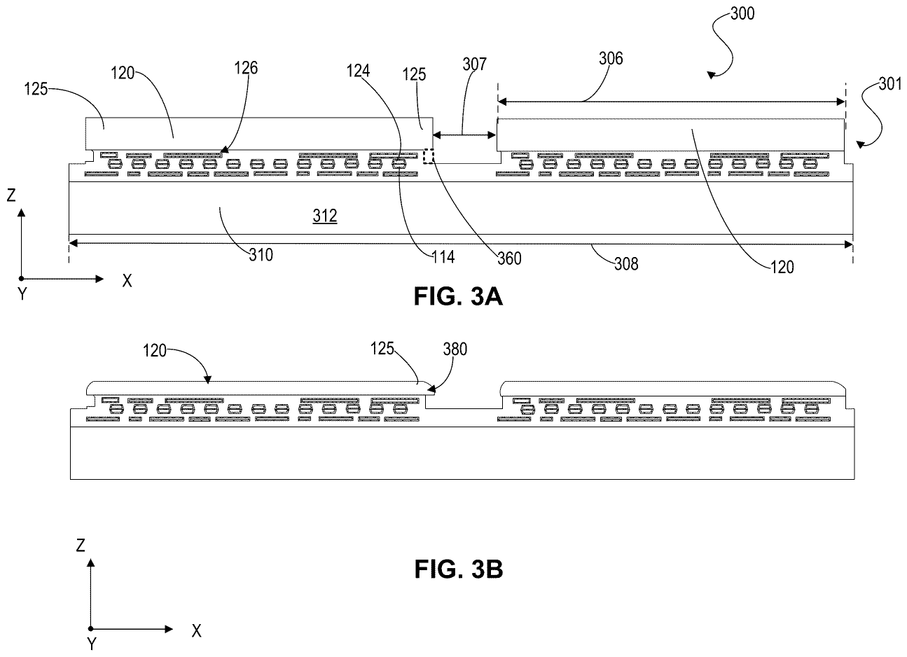

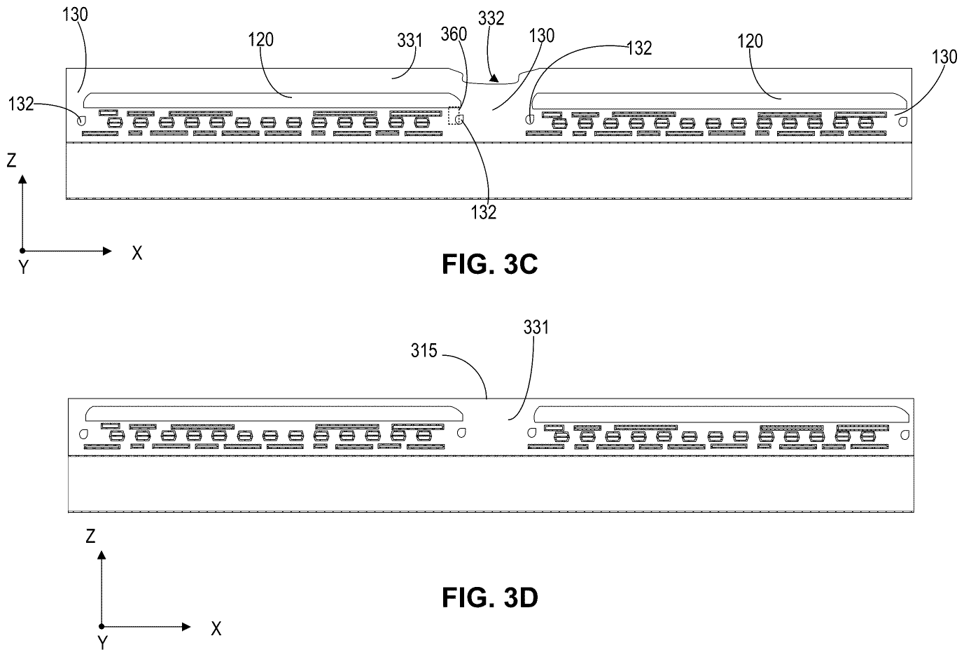

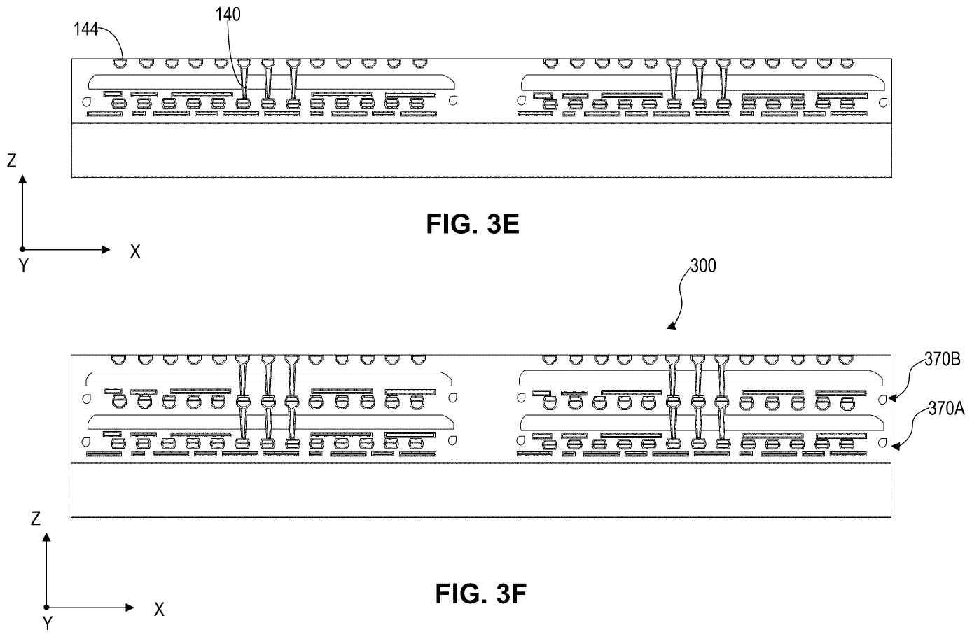

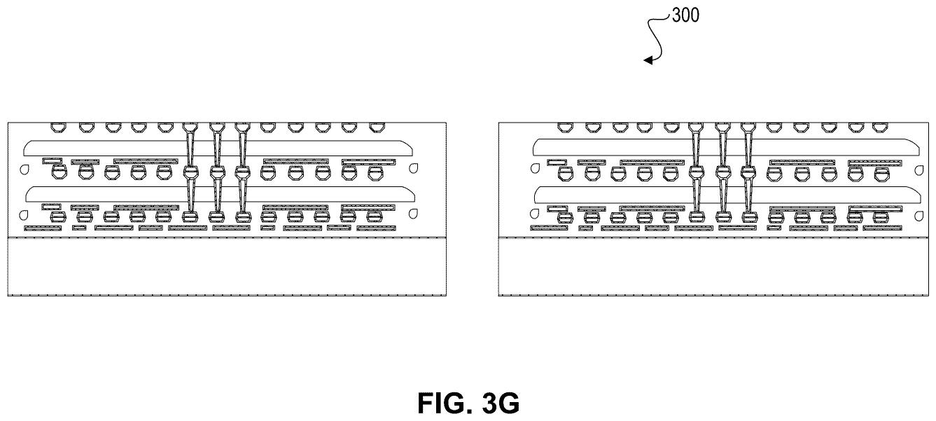

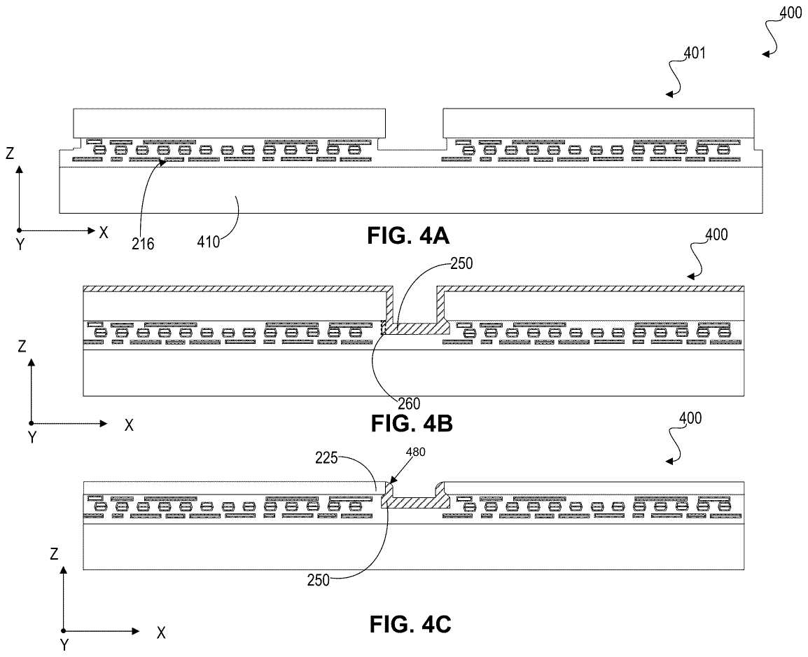

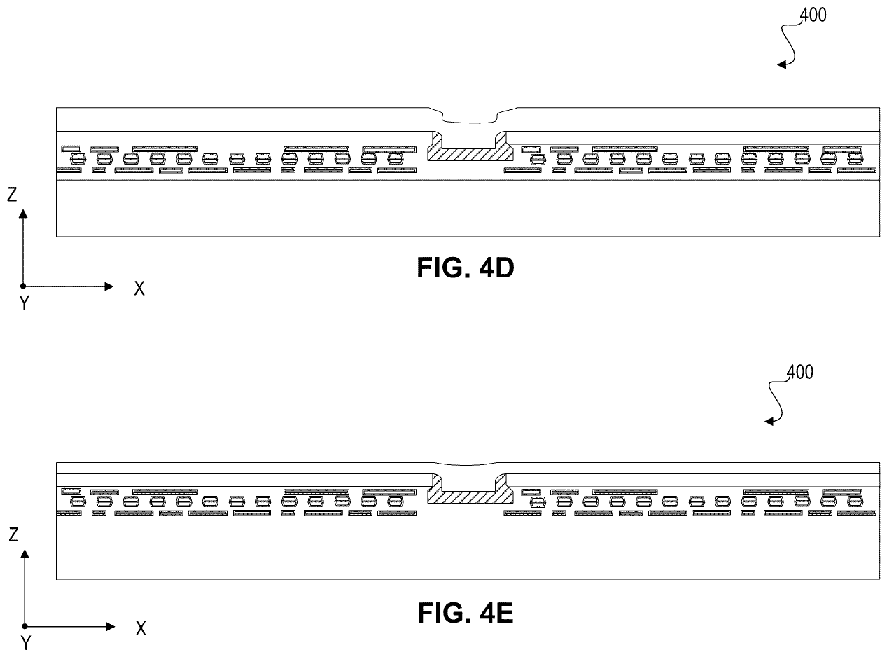

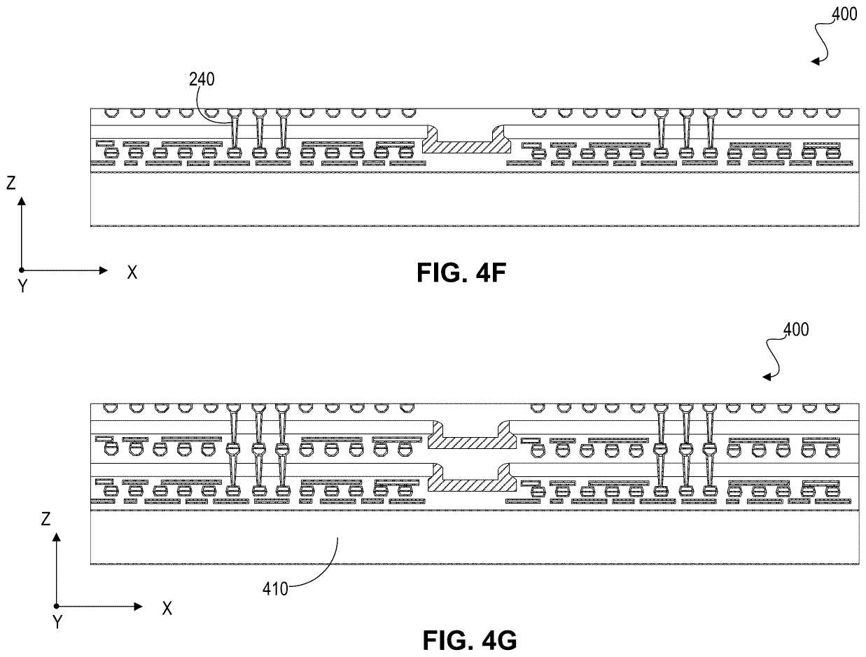

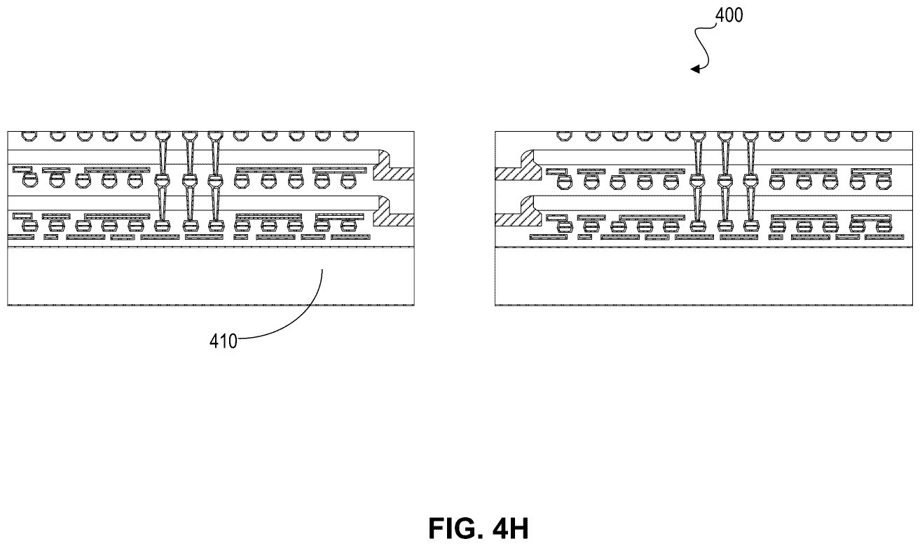

Referring to FIG. 2B, in some implementations, the filling layer 250 at least partially fills an undercut region 260 that is between the end portion 225 of the second substrate 222 and the first semiconductor structure 210. The undercut region 260 can be free of conductive structures, circuits or memory arrays. As described in further details below in reference to FIGS. 3A-4H, the undercut region 260 can refer to an empty region under the end portion 225 of the second substrate 222 that may result from a dicing process for obtaining the second semiconductor structure 220 (e.g., in a die configuration) from a wafer. In some implementations, the undercut region 260 extends from the lower surface of the second substrate 1122 to the corresponding interface A1 between the first semiconductor structure 210 and the second semiconductor structure 220 (or to the corresponding interface A2 between two second semiconductor structures 220). In some implementations, the undercut region 260 does not extend directly from the lower surface of the second substrate 222. While the undercut region 260 shown in FIG. 2A has a rectangular shape, the undercut region 260 can have any shape (e.g., regular or irregular shape). Additionally, while the filling layers 250 shown in FIG. 2A extend below the corresponding interfaces A1, A2 along Z direction, in some implementations, the filling layers 250 can be above the corresponding interfaces A1, A2. In other words, the filling layers 250 may not extend into the first semiconductor structure 210 or the corresponding lower second semiconductor structure 220. It is to be noted that in a real device, the interface A1, A2 may or may not be distinguishable at the region where the filling layer 250 is located.

In some implementations, referring to FIG. 2B, the filling layer 250 includes (i) a first portion 250A in contact with the end portion 225 of the second substrate 222 along X direction, (ii) a second portion 250B in the undercut region 260, and (iii) a third portion 250C extending from the second portion 250B along the X direction. Three portions can be connected together to form a uniform layer. In some implementations, the first portion 250A is above the second portion 250B and the third portion 250C along the Z direction.

In some implementations, different from the semiconductor device 100 where the roll-off profile is on the perimeter portion of the second substrate 122, the roll-off profile in the semiconductor device 200 can be on the first portion 250A of the filling layer 250. As shown in FIG. 2B, the first portion 250A of the filling layer 250 can have a first side 251 in contact with the end portion 225 of the second substrate 222 and a second side 253 opposite to the first side 251 along the X direction. Because of the roll-off profile, the thickness of the first portion 250A along the Z direction decreases from the first side 251 of the first portion 250A to the second side 253 of the first portion 250A. For example, the thickness 255 of the first side 251 of the first portion 250A can be greater than the thickness 255 of the second side 253 of the first portion 250A. As described below in greater details in reference to FIGS. 4A-4H, the roll-off profile of the first portion 250A of the filling layer 250 can be from a polishing process.

Although not shown in FIG. 2B, the roll-off profile can extend to the end portion 225 of the second substrate 222 in the semiconductor device 200. In the example implementations where the roll-off profile extend to the end portion 225, the thickness of the end portion 225 can be gradually decrease towards the first portion 250A of the filling layer 250. Accordingly, at the interface between the second substrate edge and the first portion 250A of the filing layer, the thickness of the second substrate along the Z direction can be same as or substantially similar to the thickness of the first side 251 of the first portion 250A. However, due to different material properties of the second substrate 222 and the filling layer 250, the slope of the roll-off profile in the second substrate 222 can be different from the slope of the roll-off profile in the first portion 250A of the filling layer 250.

FIGS. 3A-3G illustrate cross-sectional views of a semiconductor device 300 at various stages of a manufacturing process. The semiconductor device 300 can include one or more the semiconductor devices 100 of FIGS. 1A-1D.

As illustrated in FIG. 3A, a package 301 can be provided. The package 301 can include a base semiconductor structure 310 and at least one second semiconductor structure 120 that are stacked along Z direction. The base semiconductor structure 310 can include one or more first semiconductor structures 110 of FIG. 1A that are arranged laterally along X direction. In some implementations, the base semiconductor structure 310 is in a wafer configuration and has a plurality of first semiconductor structures 110 that are laterally arranged. The second semiconductor structure 120 can be in a die configuration (e.g., obtained by a dicing process that cuts a wafer into individual chips or dies). Therefore, the package 301 can include a plurality of dies stacked over a wafer, and the plurality of dies can be arranged along a lateral direction (e.g., X and/or Y directions). The example implementation shown in FIG. 3A illustrates two second semiconductor structures 120 (e.g., dies) on different positions of the base semiconductor structure 310 (e.g., a wafer, or a portion of the wafer). Each of the two second semiconductor structures 120 can be bonded to the base semiconductor structure 310 through die-to-wafer bonding techniques. For example, individual second semiconductors structures 120 (e.g., individual dies) can be directly bonded to the base semiconductor structure 310 by flipping the die upside down and connecting the dies and the wafer through contact structures. In some examples, the contact structures include bonding alloy, e.g., a mixture of metals (or metals and other elements). The bonding process can include hybrid bonding by heating the metals to create a stronger bond between conduct structures and to form a Si-O-Si interface between dielectric layers.

In some implementations, as shown in FIG. 3A, along X direction, a size 308 of the base substrate 312 of the base semiconductor structure 310 is greater than a size 306 of each of the second substrates 122. In some implementations, the size 306 of each of the second substrates 122 is 1,000 μm to 10,000 μm. In some implementations, the spacing distance 307 between two adjacent second substrates is 10 μm to 100 μm.

In some implementations, an undercut region 360 is present under the perimeter portion 125 of the second substrate 122. The undercut region 360 can be between the second substrate 122 and the base semiconductor structure 310. The undercut region 360 can be exposed to air and free of any dielectric materials (e.g., silicon oxide) or conductive structures. Without being limited to any particular theory, the undercut region 360 can result from a dicing process, during which a second semiconductor wafer is cut into multiple second semiconductor structures 120. The dicing process can include, without limitation to, laser dicing, blade dicing, plasma dicing, mechanical punch dicing, chemical etching dicing, or laser assisted water jet dicing.

The base semiconductor structure 310 can further include the circuitry 116 and the first contact structure 114 on the base substrate 312. The second semiconductor structure 120 can include the second substrate 122, the memory array 126 and the second contact structure 124 (e.g., also illustrated in FIG. 1A). In some implementations, the first contact structure 114 and/or the second contact structure 124 is made of a conductive material including, but not limited to W, Co, Cu, Al, TiN, TaN, polysilicon, or any combination thereof. The circuitry 116 can be coupled to the memory array 126 by the first contact structure 114 being in contact with the corresponding second contact structure 124.

As illustrated in FIG. 3B, the second substrate 122 of the second semiconductor structure 120 is polished to reduce a thickness of the second substrate 122 along the Z direction. The thickness of the second substrate 122 can be reduced at least by 30%, 40%, 50%, 60%, 70%, 80%, 90%, or 95%. In some implementations, before polishing, the thickness of the second substrate 122 of the second semiconductor structure 120 can be in a range between 30 μm and 200 μm. After polishing, the thickness of the second substrate 122 can be between 3 μm and 20 μm.

In some implementations, after polishing, the perimeter portion 125 of the second substrate 122 has an edge roll-off profile 380, where the thickness of the second substrate 122 in the perimeter portion 125 gradually decreases as it moves away from the center of the second substrate 122, as described above in reference to FIG. 1A. Without being limited to any particular theory, the edge roll-off profile 380 can be due to non-uniform material removal at the perimeter portions 125 of the second substrates 122. The perimeter portion 125 of the second substrate 122 can have a higher polishing rate compared to the center portion 123, e.g., due to the interaction between the slurry and polishing pad.

As illustrated in FIG. 3C, a dielectric layer 331 can be deposited on the thinned second substrate 122. The portion of the dielectric layer 331 that is between adjacent second semiconductor structures 120 and/or laterally surrounding the second semiconductor structures 120 can be referred to as a dielectric structure 130 in the present disclosure. As noted above, the dielectric structure 130 may also extend between a second semiconductor structure 120 and the base semiconductor structure 310. As the dielectric layer at least partially fills the empty space between adjacent second semiconductor structures 120, a dishing may be present at this step. The size of the dishing can be a few microns along Z direction. The dielectric layer 331 can include dielectric materials including, but not limited to, silicon oxide, silicon nitride, silicon oxynitride, or any combination thereof. The dielectric layer 331 can be deposited using one or more thin film deposition techniques, including, but not limited to, chemical vapor deposition (CVD), physical vapor deposition (PVD), plasma enhanced chemical vapor deposition (PECVD), sputtering, or any combination thereof.

A portion of the dielectric structure 130 can at least partially fill the undercut region 360 under the perimeter portion 125 of the second substrate 122. During the deposition process of the dielectric layer 331, air gaps 132 can be formed in the dielectric structure 130 and adjacent to the perimeter portions 125 of the second substrates 122. In some examples, air gaps 132 can be at least partially inside the undercut region 360.

As illustrated in FIG. 3D, a polishing process can be performed to reduce the thickness of the dielectric layer 331 that is above the second substrate 122 and to form an even upper surface 315. The polishing process can include, but not limited to, chemical mechanical polishing (CMP), mechanical polishing, electrochemical polishing, ultrasonic polishing, or any combination thereof. After polishing, the thinned dielectric layer 331 with an even upper surface 315 can remain on the second substrate 122.

As illustrated in FIG. 3E, at least one first TSVs 140 can be formed extending vertically through the polished second substrates 122 of the second semiconductor structures 120. The first TSVs 140 can land on the corresponding second contact structures 124 and be coupled to the base semiconductor structure 310 through corresponding first and second contact structures 114, 124. Forming TSVs 140 can include forming a deep hole into the second substrate 122 followed by a deposition process to fill the etched holes with a conductive material. If the second substrate 122 is thick (e.g., 200 μm), the lateral width of the TSVs 140 may need be increased to maintain an aspect ratio (e.g., depth-to-width ratio) at a suitable range, as high-aspect-ratio TSVs can make the fabrication more challenging. As the thickness of the second substrate 122 is reduced during the polishing process described in reference to FIG. 3B, a shallower TSV 140 can be formed. Therefore, the size of the TSVs 140 can also be reduced while maintaining the aspect ratio of the TSV 140 at the suitable range. Additionally, without being limited to any particular theory, a thinner second substrate 122 can reduce mechanical stress during the fabrication process, thereby allowing TSVs 140 to be placed closer together with reduced or without mechanical failures. Therefore, with the thinned substrate, TSVs 140 can have a smaller lateral size and a smaller pitch, thereby increasing the I/O density of the semiconductor device 300.

With continued reference to FIG. 3E, at least one third contact structures 144 can be formed on the first TSVs 140. The third contact structures 144 can be at least one of micro-bumps, solder balls, pillars, or bonding pads. Adjacent third contact structures 144 can be separated by a dielectric material. The third contact structures 144 can be made of a conductive material including, but not limited to W, Co, Cu, Al, TiN, TaN, polysilicon, or any combination thereof. The third contact structures 144 can be formed by a plurality of processes including, but not limited to, photolithography, dry/wet etch, thin film deposition, thermal growth, implantation, chemical mechanical polishing (CMP), and any other suitable processes.

As illustrated in FIG. 3F, more second semiconductor structures 120 can be stacked over the package 301. The example implementation depicted in FIG. 3F has a total of two layers of second semiconductor structures 120 that are vertically stacked, but is not limited thereto. The semiconductor device 300 can include any suitable number of layers of second semiconductor structures 120 (e.g., 1, 3, 4, 5, 6, or 7) that are sequentially stacked together along Z direction. The process of stacking additional layer of second semiconductor structures 120 on the package 301 can be the same as or similar to the process described above in reference to FIGS. 3A-3E. In other words, the process described above in reference to FIGS. 3A-3E can be repeated multiple times to sequentially stack multiple layers of second semiconductor structures 120 on the base semiconductor structure 310. However, instead of stacking additional semiconductor structure onto the base semiconductor structure 310 (as shown in FIG. 3A), at each repeated process loop, the second semiconductor structure 120 can be stacked sequentially on another second semiconductor structure 120.

In some implementations, as noted above, the base semiconductor structure 310 is in a wafer configuration. Therefore, each layer of second semiconductor structures 120 can include multiple second semiconductor structures 120. While the example implementation depicted in FIG. 3F shows each layer having two second semiconductor structures 120 arranged laterally, in some implementations, a layer can include any other suitable number of second semiconductor structures 120 (e.g., 1, 10, 20, 50, 100, 500, or 1000).

For each of the second semiconductor structure 120, the second substrate 122 can be thinned before forming the TSVs 140 extending through the corresponding second substrate 122. The TSVs 140 of each layer can be vertically stacked together, as shown in FIG. 3F, to couple corresponding second semiconductor structures 120 to the base semiconductor structure 310. In some implementations, the substrate of the topmost second semiconductor structure 120 (e.g., the one that is farthest away from base semiconductor structure 310) may not be thinned, as the top-most layer may not include TSVs 140. As a result, a thickness of the topmost second substrate 122 can be greater than a thickness of each of other second substrates 122. For example, the thickness of the topmost second substrate 122 can be in a range between 30 μm and 200 μm, while the thickness of the thinned second substrate 122 can be between 3 μm and 20 μm.

As illustrated in FIG. 3G, after one or more layers of the second semiconductor structures 120 are stacked onto the base semiconductor structure 310, the base semiconductor structure 310 can be diced into multiple pieces, with each piece being, e.g., a first semiconductor structure 110 of FIGS. 1A-1D. Therefore, the semiconductor device 300 can be diced into multiple units, with each unit having a single first semiconductor structure 110 and one or more second semiconductor structures 120 stacked vertically over the first semiconductor structure 110. Each unit can be the semiconductor device 100 of FIGS. 1A-1D. In some implementations, the dicing process includes, without limitation to, laser dicing, blade dicing, plasma dicing, mechanical punch dicing, or laser assisted water jet dicing.

FIGS. 4A-4H illustrate cross-sectional views of a semiconductor device 400 at various stages of a manufacturing process. The semiconductor device 400 can include one or more the semiconductor devices 200 of FIGS. 2A-2C. Some processes described below for forming the semiconductor device 400 may substantially be the same as or similar to those described above for forming the semiconductor device 300 in reference to FIGS. 3A-3G. Thus, for brevity, redundant descriptions will be omitted, and the following description will mainly focus on the process differences.

As illustrated in FIG. 4A, a package 401 can be provided. The package 401 can be the same as the package 301 of FIG. 3A.

As illustrated in FIG. 4B, a filling layer 250 can be deposited. The filling layer 250 can fill the undercut region 260 that is under the edge region (or perimeter region) of the second substrate 222. In some implementations, the filling layer 250 is deposited by ALD. ALD may offer better thickness control and uniformity. Therefore, the filling layer 250 may not have air gaps, which is different from the dielectric structure 130 in FIGS. 3D-3G. Reducing air gaps can reduce the risk of peeling (e.g., peeling of the second substrate 222). Air gaps can create areas where the adhesion between layers are weak, and the air gaps may also create an area where mechanical stress can be concentrated. The weak adhesion and concentration of stress can cause the layer to lift or peel off more easily. With reduced air gaps or eliminated air gaps, the semiconductor device 400 can be more mechanically reliable. The filling layer 250 can include dielectric materials including, but not limited to, silicon oxide, silicon nitride, silicon oxynitride, or any combination thereof. In some implementations, the filling layer 250 includes silicon nitride.

As illustrated in FIG. 4C, similar to the process described above in reference to FIG. 3B, the second substrates 222 can be thinned in a polishing process. Unlike the structures shown in FIG. 3B, the end portion 225 of the second substrate 222 can be laterally surrounded by the filling layer 250. Therefore, during the polishing process, the edge roll-off profile 480 can be present in the filling layer 250, as it is farther away from the center of the second semiconductor structure 220 compared to the end portion 225 of the second substrate 222. In some implementations, the edge roll-off profile is present in the filling layer 250 only. In some implementations, the edge roll-off profile is present in both the filling layer 250 and the end portion 225 of the second substrate 222, as described above in reference to FIGS. 2A-2C.

FIGS. 4D-4H illustrate the process steps to form TSVs and contact structures, stack multiple second semiconductor structures 220 vertically on the base semiconductor structure 410, and dice the base semiconductor structure 410 into separate pieces. These process steps can be same as or substantially similar to the process steps described above in reference to FIGS. 3D-3G.

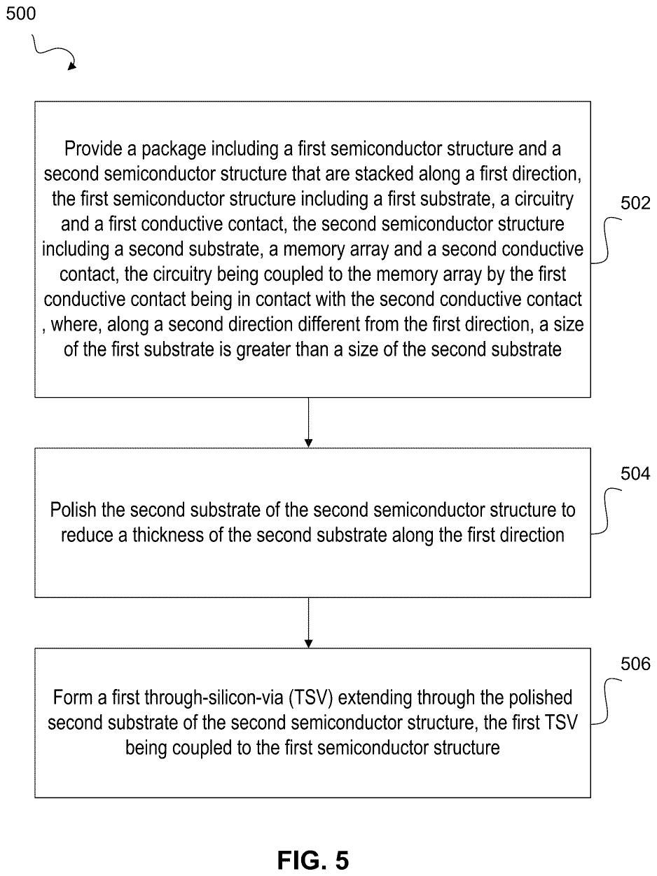

FIG. 5 is a flowchart of a process of an example method 500 of forming a semiconductor device. The semiconductor device can be, e.g., the semiconductor device 100 of FIGS. 1A-1D, or the semiconductor device 200 of FIGS. 2A-2C.

At step 502, a package is provided. The package includes a base semiconductor structure and a second semiconductor structure that are stacked along a first direction. The base semiconductor structure includes a base substrate, a circuitry and a first contact structure. The second semiconductor structure includes a second substrate, a memory array and a second contact structure. The circuitry is coupled to the memory array by the first contact structure being in contact with the second contact structure. Along a second direction different from the first direction, a size of the base substrate is greater than a size of the second substrate. The package can be, e.g., the package 301 of FIG. 3A, or the package 401 of FIG. 4A. The base semiconductor structure can be, e.g., the base semiconductor structure 310 of FIGS. 3A-3G, or the base semiconductor structure 410 of FIGS. 4A-4H. The base substrate can be, e.g., the base substrate 312 of FIGS. 3A-3G, or the base substrate 412 of FIGS. 4A-4H. The circuitry can be, e.g., the circuitry 116 of FIGS. 1A-1D and 3A-3G, or the circuitry 216 of FIGS. 2A-2C and 4A-4H. The first contact structure can be, e.g., the first contact structure 114 of FIGS. 1A-1D and 3A-3G, or the first contact structure 214 of FIGS. 2A-2C and 4A-4H. The second semiconductor structure can be, e.g., the second semiconductor structure 120 of FIGS. 1A-1D and 3A-3G, or the second semiconductor structure 220 of FIGS. 2A-2C and 4A-4H. The second substrate can be, e.g., the second substrate 122 of FIGS. 1A-1D and 3A-3G, or the second substrate 222 of FIGS. 2A-2C and 4A-4H. The memory array can be, e.g., the memory array 126 of FIGS. 1A-1D and 3A-3G, or the memory array 226 of FIGS. 2A-2C and 4A-4H. The second contact structure can be, e.g., the second contact structure 124 of FIGS. 1A-1D and 3A-3G, or the second contact structure 224 of FIGS. 2A-2C and 4A-4H. The size of base substrate can be, e.g., the size 308 of base substrate of FIG. 3A. The size of the second substrate can be, e.g., the size 106 of the second substrate of FIG. 2A, or the size 306 of the second substrate of FIG. 3A.

At step 504, the second substrate of the second semiconductor structure is polished to reduce a thickness of the second substrate along the first direction, as described above in reference to FIGS. 3B and 4C.

At step 506, a first through-silicon-via (TSV) is formed extending through the polished second substrate of the second semiconductor structure. The first TSV is coupled to the base semiconductor structure. The first TSV can be, e.g., the TSV 140 of FIGS. 1A-1D and 3A-3G, or the TSV 240 of FIGS. 2A-2C and 4A-4H.

In some implementations, providing the package includes: providing the package including the base semiconductor structure and a plurality of second semiconductor structures. The plurality of second semiconductor structures includes the second semiconductor structure. There is an undercut region under the second substrate and between the second substrate and the base substrate. The plurality of second semiconductor structures are stacked over the base semiconductor structure along the first direction, and the plurality of second semiconductor structures are spaced part from one another along the second direction. The undercut region can be, e.g., the undercut region 260 of FIGS. 2A-2C and FIGS. 4A-4H, or the undercut region 360 of FIGS. 3A-3G.

In some implementations, the second substrate includes an end portion and a center portion along the second direction, and the undercut region is under the end portion. After polishing the second substrate, the end portion includes a perimeter portion having a thickness smaller than a thickness of the center portion. The end portion can be, e.g., the end portion 225 of FIGS. 2A-2C and 4A-4H. The center portion can be, e.g., the center portion 123 of FIGS. 1A-1D and 3A-3G, or the center portion 223 of FIGS. 2A-2C and 4A-4H. The perimeter portion can be, e.g., the perimeter portion 125 of FIGS. 1A-1D and 3A-3G. The thickness of the perimeter portion can be, e.g., the thickness 102 of the perimeter portion 125 of FIG. 1A. The thickness of the center portion can be, e.g., the thickness 104 of the center portion 123 of FIG. 1A.

In some implementations, the method includes depositing a filling material to form a filling layer between adjacent second semiconductor structures of the plurality of second semiconductor structures. The filling material fills the undercut region. The method includes polishing corresponding second substrates of the plurality of second semiconductor structures to reduce thicknesses of the corresponding second substrates along the first direction. The filling layer can be, e.g., the filling layer 250 of FIGS. 2A-2C and 4B-4H.

In some implementations, the method includes polishing second substrates of the plurality of second semiconductor structures to reduce thicknesses of the second substrates along the first direction; forming TSVs through corresponding polished second substrates of the plurality of second semiconductor structures, where the TSVs including the first TSV; and after forming the TSVs through the corresponding polished second substrates, cutting the package into a plurality of chip packages. A chip package of the plurality of chip packages includes a portion of the base semiconductor structure and a corresponding second semiconductor structure of the plurality of second semiconductor structures that is stacked over the portion of the base semiconductor structure. The chip package can be, e.g., the semiconductor device 100 of FIGS. 1A-1D, or the semiconductor device 200 of FIGS. 2A-2D. The portion of the base semiconductor structure can be, e.g., the first semiconductor structure 110 of FIGS. 1A-1D and 3G, or the first semiconductor structure 210 of FIGS. 2A-2D and 4H.

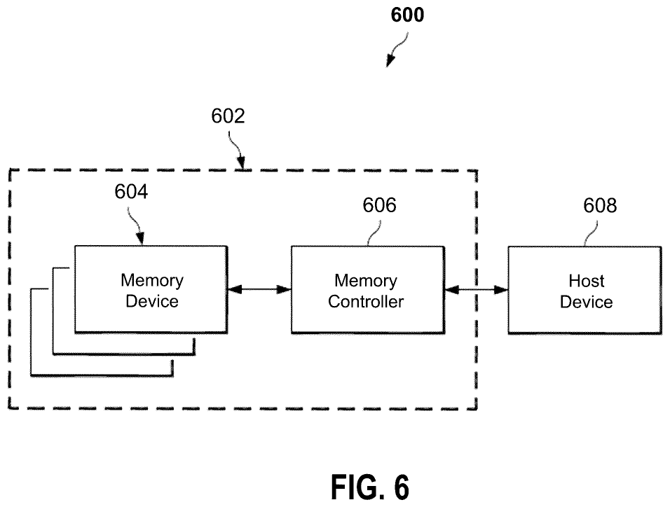

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the semiconductor device 100 of FIGS. 1A-1D and 3G, the semiconductor device 200 of FIGS. 2A-2C and 4H, the semiconductor device 300 of FIGS. 3A-3F, or the semiconductor device 400 of FIGS. 4A-4G.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multi-media card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +−0.10%, +−0.20%, or +−0.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, including:
a first semiconductor structure including a first substrate and a first contact structure; and
a second semiconductor structure stacked over the first semiconductor structure along a first direction and having a second substrate and a second contact structure, the second semiconductor structure being coupled to the first semiconductor structure with the first contact structure being in contact with the second contact structure along the first direction,
where the second substrate has a perimeter portion and a center portion along a second direction different from the first direction, where, along the first direction, a thickness of the perimeter portion of the second substrate is smaller than a thickness of the center portion of the second substrate, and where, along the second direction, a size of the first substrate is greater than a size of the second substrate.

2. The semiconductor device of claim 1, including:
a dielectric structure including a dielectric material between the first semiconductor structure and the second semiconductor structure, the dielectric structure including an air gap, and the air gap is closer to the perimeter portion of the second substrate of the second semiconductor structure than to the first semiconductor structure.

3. The semiconductor device of claim 1, where the thickness of the perimeter portion of the second substrate gradually decreases from a first side of the perimeter portion of the second substrate to a second side of the perimeter portion of the second substrate, the first side of the perimeter portion of the second substate being between the center portion of the second substrate and the second side of the perimeter portion of the second substrate.

4. The semiconductor device of claim 1, where the size of the first substrate is greater than the size of the second substrate by 10 μm to 100 μm.

5. The semiconductor device of claim 1, where the thickness of the perimeter portion of the second substrate decreases by a value over a distance along the second direction, the value being between 50 nm and 1000 nm, the distance being smaller than 1000 μm.

6. The semiconductor device of claim 1, where the second semiconductor structure includes a memory array having a plurality of memory cells, and the first semiconductor structure includes a circuitry configured to be coupled to the memory array through at least the first contact structure and the second contact structure.

7. The semiconductor device of claim 1, where the first contact structure and the second contact structure include at least one of micro-bumps, solder balls, or bonding pads.

8. The semiconductor device of claim 1, including:
a through-silicon-via (TSV) extending through the second substrate of the second semiconductor structure along the first direction onto a corresponding second contact structure of the second semiconductor structure that is in contact with a corresponding first contact structure of the first semiconductor structure.

9. The semiconductor device of claim 1, including:
a plurality of second semiconductor structures sequentially stacked over the first semiconductor structure along the first direction, the plurality of second semiconductor structures including the second semiconductor structure, the plurality of second semiconductor structures being coupled to one another through hybrid bonding.

10. The semiconductor device of claim 9, including:
a plurality of through-silicon-vias (TSVs) extending through the plurality of second semiconductor structures along the first direction and coupling the plurality of second semiconductor structures to the first semiconductor structure,
where the plurality of TSVs are stacked along the first direction and coupled to one another, and at least one TSV of the plurality of TSVs extends through a second substrate of a corresponding second semiconductor structure of the plurality of second semiconductor structures.

11. A semiconductor device, including:
a first semiconductor structure including a first substrate and a first contact structure;
a second semiconductor structure including a second substrate and a second contact structure, where the second semiconductor structure is stacked over the first semiconductor structure along a first direction, the second semiconductor structure is coupled to the first semiconductor structure with the first contact structure being in contact with the second contact structure along the first direction, the second substrate has an end portion and a center portion along a second direction different from the first direction, and, along the second direction, a size of the first substrate is greater than a size of the second substrate; and
a filling layer at least partially surrounding the end portion of the second substrate, where the filling layer fills an undercut region that is under the end portion of the first substrate, and the undercut region is between the end portion of the second substrate and the first substrate.

12. The semiconductor device of claim 11, where the filling layer includes a first portion in contact with the end portion of the second substrate along the second direction, a second portion in the undercut region, and a third portion extending from the second portion along the second direction, and
where the first portion has a first side in contact with the end portion of the second substrate and a second side opposite to the first side along the second direction, and a thickness of the first portion along the first direction decreases from the first side of the first portion to the second side of the first portion.

13. The semiconductor device of claim 12, where, for the filling layer, the first portion is above the second portion and the third portion along the first direction.

14. The semiconductor device of claim 11, where the second semiconductor structure includes a memory array having a plurality of memory cells, and the first semiconductor structure includes a circuitry configured to be coupled to the memory array through at least the first contact structure and the second contact structure.

15. The semiconductor device of claim 11, including:
a through-silicon-via (TSV) extending through the second substrate of the second semiconductor structure along the first direction onto a corresponding second contact structure of the second semiconductor structure that is in contact with a corresponding first contact structure of the first semiconductor structure.

16. A method, including:
providing a package including a base semiconductor structure and a second semiconductor structure that are stacked along a first direction, the base semiconductor structure including a base substrate, a circuitry and a first contact structure, the second semiconductor structure including a second substrate, a memory array and a second contact structure, the circuitry being coupled to the memory array by the first contact structure being in contact with the second contact structure, where, along a second direction different from the first direction, a size of the base substrate is greater than a size of the second substrate;
polishing the second substrate of the second semiconductor structure to reduce a thickness of the second substrate along the first direction; and
forming a first through-silicon-via (TSV) extending through the polished second substrate of the second semiconductor structure, the first TSV being coupled to the base semiconductor structure.

17. The method of claim 16, where providing the package includes:
providing the package including the base semiconductor structure and a plurality of second semiconductor structures including the second semiconductor structure, where there is an undercut region under the second substrate and between the second substrate and the base substrate,
where the plurality of second semiconductor structures are stacked over the base semiconductor structure along the first direction, and the plurality of second semiconductor structures are spaced part from one another along the second direction.

18. The method of claim 17, where the second substrate includes an end portion and a center portion along the second direction, and the undercut region is under the end portion, and,
where, after polishing the second substrate, the end portion includes a perimeter portion having a thickness smaller than a thickness of the center portion.

19. The method of claim 17, including:
depositing a filling material to form a filling layer between adjacent second semiconductor structures of the plurality of second semiconductor structures, where the filling material fills the undercut region; and
polishing corresponding second substrates of the plurality of second semiconductor structures to reduce thicknesses of the corresponding second substrates along the first direction.

20. The method of claim 17, including:
polishing second substrates of the plurality of second semiconductor structures to reduce thicknesses of the second substrates along the first direction;
forming TSVs through corresponding polished second substrates of the plurality of second semiconductor structures, the TSVs including the first TSV; and
after forming the TSVs through the corresponding polished second substrates, cutting the package into a plurality of chip packages, a chip package of the plurality of chip packages including a portion of the base semiconductor structure and a corresponding second semiconductor structure of the plurality of second semiconductor structures that is stacked over the portion of the base semiconductor structure.
